(19) United States
(12) Patent Application Publication
(10) Pub. No.: US 2021/0002179 A1
(43) Pub. Date: Jan. 7, 2021

(54) COPPER-CERAMIC SUBSTRATE

(71) Applicant: AURUBIS STOLBERG GMBH & CO. KG, STOLBERG (DE)

(72) Inventors: HELGE LEHMANN, HUERTGENWALD (DE); KARL ZEIGER, ESCHWEILER (DE); BENJAMIN CAPPI, NEU-MORESNET (BE)

(21) Appl. No.: 16/980,140

(22) PCT Filed: Mar. 20, 2018
(86) PCT No.: PCT/EP2018/056957

§ 371 Date: Sep. 11, 2020

(51) Int. Cl. C04B 37/02

(52) U.S. Cl. CPC C04B 37/021; C04B 2235/786; C04B 2235/96; C04B 2237/407

(57) ABSTRACT

The invention relates to a copper-ceramic substrate comprising:
a ceramic carrier, and
at least one copper layer bonded to a surface of the ceramic carrier, which has a
free surface for forming a conductor structure and/or for securing bonding wires, wherein
the copper layer has a microstructure with an average grain size diameter of 200 to 500 μm, preferably 300 to 400 μm.

The invention relates to a copper-ceramic substrate with the features of the preamble in accordance with claim 1.

Copper-ceramic substrates (e.g., DCB, AMB) are used, for example, to manufacture electronic power modules and are a composite of a ceramic carrier having copper layers either on one side or on both sides. The copper layers are prefabricated as semi-finished copper products in the form of a copper foil usually with a thickness of 0.1 to 1.0 mm and are connected to the ceramic carrier using a connection method. Such connection methods are also known as DCB (direct copper bonding) or as AMB (active metal brazing). In the case of a higher strength of the ceramic carrier, however, copper plies or copper layers with an even greater thickness can also be applied, which is fundamentally advantageous with regard to the electrical and thermal properties.

Ceramic plates made of, for example, mullite, Al₂O₃, Si₃N₄, AlN, ZTA, ATZ, TiO₂, ZrO₂, MgO, CaO, CaCO₃, or a mixture of at least two of these materials are used as the ceramic carrier.

In the DCB method, the copper ply is connected to the ceramic base using the following method steps:
oxidizing the copper ply in such a way that a uniform copper oxide layer results;
placing the copper ply onto the ceramic carrier;
heating the composite to a process temperature between 1060° C. and 1085° C.

This creates an eutectic melt on the copper ply, which forms a substance-to-substance bond with the ceramic carrier. This process is known as bonding. If Al₂O₃ is used as a ceramic carrier, a thin Cu—Al spinel layer is created by the bonding.

Following the bonding process, the necessary conductor tracks are structured by etching the surface of the copper ply facing the outside, i.e., the free surface of the copper ply. The chips are then soldered on and the connections to the contacts on each upper side of the chips are made by applying bonding wires, for which purpose the microstructure of the free surface of the copper layer should be as homogeneous and finely structured as possible. The copper-ceramic substrate can then additionally be connected to a base plate in order to produce power modules.

The advantages of the copper-ceramic substrate described lie above all in the high current-carrying capacity of the copper and good electrical insulation and mechanical support from the ceramic carrier. Furthermore, the DCB technology allows the copper ply to adhere well to the ceramic carrier. In addition, the copper-ceramic substrates used are stable at a high ambient temperature, which are often present in the application.

The weak point of copper-ceramic substrates is the so-called thermal shock resistance, a material parameter that describes the failure of a component after a specific number of temporary thermally induced stresses. This parameter is important for the service life of the power modules since extreme temperature gradients result during the operation of the modules. Due to the different coefficients of thermal expansion of the ceramic and copper materials used, mechanical stresses are thermally induced during use in the copper-ceramic substrate, which after a specific number of cycles results in delamination of the copper layer from the ceramic layer and/or in cracks in the ceramic layer and/or in the copper layer and thus can result in failure of the component.

Generally, copper-ceramic substrates having a copper layer with a fine microstructure have the advantage that they have advantages in terms of optical inspection, the bonding ability, the etching behaviour, the grain boundary formation, the galvanisability and the further processing in general. However, it is disadvantageous that, owing to the higher thermally induced stresses in the event of temperature fluctuations, they have a shorter service life and poorer resistance to temperature changes.

Conversely, copper-ceramic substrates having a copper layer with a coarser microstructure have the advantage of a longer service life but are disadvantageous with regard to the additional requirements described above.

DE 10 2015 224 464 A1 discloses a copper-ceramic substrate in which the microstructure of the copper layer on the side facing the ceramic carrier deliberately has a larger grain size than on the free surface.

The advantage of this solution can be seen in the fact that the copper layer on the free surface can be structured lightly and very fine due to the smaller grain size of the microstructure, while the copper layer on the side facing the ceramic carrier has better thermal shock resistance in accordance with the Hall-Petch relationship due to the larger grain size. The copper-ceramic substrate can thus be improved in such a way that it has better properties with regard to the different requirements described above. The targeted selection of the grain sizes on both sides of the copper layer creates a new design parameter by means of which the copper-ceramic substrate can be designed in an improved manner with regard to both requirements.

A disadvantage of this solution can be seen in the fact that the implementation of the different grain sizes represents an additional effort. For example, to realise the different grain sizes, it is conceivable to produce the copper layer by plating two different copper layers with different grain sizes, which represents an additional workload with associated costs. As a result, the copper-ceramic substrate of DE 10 2015 224 464 A1 becomes more expensive and is therefore only suitable for special applications that justify the higher price.

Against this background, the object of the invention is to provide a copper-ceramic substrate which can be produced more cost-effectively than the copper-ceramic substrate from the publication DE 10 2015 224 464 A1 and which nevertheless satisfies the various requirements.

According to the invention, a copper-ceramic substrate having the features of the preamble in accordance with claim 1 is proposed to achieve the object. Further preferred developments can be found in the dependent claims.

According to the basic idea of the invention, it is proposed that the copper layer has a microstructure with an average grain size diameter of 200 to 500 μm, preferably 300 to 400 μm.

The grain of the microstructure need not only have grain sizes in the proposed ranges in this case; the distribution of the grain sizes corresponds to a monomodal Gaussian distribution and it is possible that a small proportion of the grains also have grain sizes less or more than 200 or 500 μm or less or more than 300 μm or 400 μm. It is only important that the average grain size is within the proposed ranges. The grain size diameter can be determined, for example, using the linear intercept method described in ASTM 112-13. Grains with grain sizes larger than 1000 μm must however be avoided in any case.

The proposed microstructure of the copper layer can be realised either directly during the bonding on the ceramic carrier, for example by adhering to predetermined throughput or dwell times and the choice of the temperature in the lead and lag of the bonding process, or also by means of a separate temperature aftertreatment.

The advantage of the proposed copper-ceramic substrate can be seen in the fact that it has a sufficiently long service life, since by choosing the average grain size diameter the grain have an average size, by means of which, in accordance with the Hall-Petch relationship, a sufficiently low stress level can be realised in the substrate during the temperature-induced alternating bending load occurring under normal use in order to achieve the desired long service life. In addition, the requirements for bondability, optical inspection, the etching or cutting process required to introduce the conductor structure, and additional specific requirements can be met, for which purpose an average grain size of less than 500 μm or particularly preferably less than 400 μm is advantageous.

In order to achieve these advantageous properties of the microstructure of the copper layer after the temperature treatment process, it is further proposed that
the copper layer
has a proportion of at least 99.95% Cu, preferably at least 99.99% Cu.

Furthermore, the copper layer can preferably have a proportion of
at most 25 ppm Ag.

According to a further preferred embodiment, the copper layer can have a proportion of
at most 10 ppm, preferably at most 5 ppm O.

It is further proposed that

the copper layer has a proportion of the elements Cd, Ce, Ge, V, Zn of, in each case, at most 0-1 ppm, wherein
the copper layer according to a further preferred embodiment has a proportion of the elements Cd, Ce, Ge, V, Zn of a total of at least 0.5 ppm and at most 5 ppm.

It is further proposed that
the copper layer has a proportion of the elements Bi, Se, Sn, Te of, in each case, at most 0-2 ppm, wherein
the copper layer according to a further preferred embodiment has a proportion of the elements Bi, Se, Sn, Te of a total of at least 1.0 ppm and at most 8 ppm.

It is further proposed that
the copper layer has a proportion of the elements Al, Sb, Ti, Zr of, in each case, at most 0-3 ppm, wherein
the copper layer according to a further preferred embodiment has a proportion of the elements Al, Sb, Ti, Zr of a total of at least 1.0 ppm and at most 10 ppm.

It is further proposed that
the copper layer has a proportion of the elements As, Co, In, Mn, Pb, Si of, in each case, at most 0-5 ppm, wherein
the copper layer according to a further preferred embodiment has a proportion of the elements As, Co, In, Mn, Pb, Si of a total of at least 1.0 ppm and at most 20 ppm.

It is further proposed that
the copper layer has a proportion of the elements B, Be, Cr, Fe, Mn, Ni, P, S of, in each case, at most 0-10 ppm, wherein
the copper layer according to a further preferred embodiment has a proportion of the elements B, Be, Cr, Fe, Mn, Ni, P, S of a total of at least 1.0 ppm and at most 50 ppm.

It is further proposed that
the copper layer has a proportion of the elements mentioned in claims 4 to 16, including further impurities, of preferably at most 50 ppm.

The invention is explained below on the basis of preferred embodiments with reference to the accompanying drawings, in which:

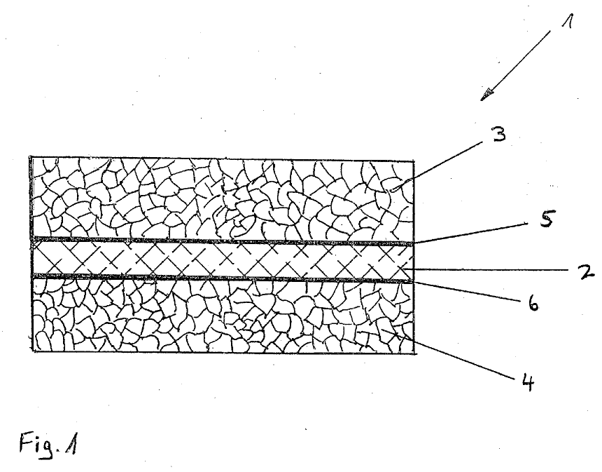

FIG. 1 is a copper-ceramic substrate according to the invention having two copper layers

Power modules are semiconductor components of power electronics and are used as semiconductor switches. They contain a plurality of power semiconductors (chips) that are electrically insulated from the heat sink in one housing. These are applied to a metallised surface of an electrically insulating plate (for example made of ceramic) by means of soldering or gluing, so that on the one hand the heat conduction towards the base plate is ensured and on the other hand the electrical insulation is ensured. The composite of metallised layers and insulating plate is called a copper-ceramic substrate and is realised on an industrial scale using the so-called DCB technology (direct copper bonding technology).

The chips are contacted by bonding with thin bonding wires. In addition, further modules with different functions (e.g., sensors, resistors) can be present and integrated.

To produce a DCB substrate, ceramic carriers (e.g., Al₂O₃, Si₃N₄, AlN, ZTA, ATZ) are bonded to one another on the top and bottom using copper plies in a bonding process. In preparation for this process, the copper plies can, before being placed onto the ceramic carrier, be surface-oxidised, (e.g., chemically or thermally) and subsequently can be placed onto the ceramic carrier. The connection is created in a high temperature process between 1060° C. and 1085° C., wherein a eutectic melt is created on the surface of the copper ply, which forms a connection with the ceramic carrier. In the case of copper (Cu) on aluminium oxide (Al₂O₃), for example, this connection consists of a thin Cu—Al spinel layer.

FIG. 1 shows a copper-ceramic substrate 1 further developed according to the invention having a ceramic carrier 2 and two copper layers 3 and 4. The two copper layers 3 and 4 developed further according to the invention have a microstructure with an average grain size diameter of 200 to 500 μm, preferably 300 to 400 μm.

The copper layers 3 and 4 can be connected to the ceramic carrier 2, for example by the DCB method described at the outset, so that they are connected to the ceramic carrier 2 by a substance-to-substance bond in the respective surface edge zone 5 and 6.

During the DCB method, the copper layers 3 and 4 are placed on the ceramic carrier 2 in the form of pre-oxidised semi-finished copper products and then heated to the process temperature from 1060° C. to 1085° C. The Cu-oxydul in the copper layers 3 and 4 melts and forms the connections in the surface edge zones with the ceramic carrier 2. Due to the effects of temperature and the recrystallization of the two copper materials, the microstructure can be set by choosing appropriate dwell times and cooling times so that the preferred average grain size diameter is set automatically. Since the influence of the temperature treatment including the cooling process is readily known to the person skilled in the art, he can select the parameters specifically so that the microstructure is formed according to the invention without a further temperature treatment being necessary. If the bonding process does not permit such a setting or if this is disadvantageous for economic reasons, the microstructure can also be achieved by a subsequent or previously carried out temperature treatment. Furthermore, the copper layers 3 and 4 preferably have a Vickers hardness of 40 to 100 after bonding.

The copper layers 3 and 4 having the microstructure according to the invention or having the proportions proposed according to the invention and in particular having the proposed proportions of O are highly conductive Cu materials and have a conductivity of 50 MS/m, preferably at least 57 MS/m and particularly preferably of at least 58 MS/m. However, materials with a lower conductivity are also conceivable. Furthermore, the copper layers 3 and 4 can, if necessary, also be supplemented by further Cu materials or layers, provided that the material properties of the copper layers 3 and 4 are to be further refined and the microstructure according to the invention is not adversely affected thereby.

The semi-finished copper products of the copper layers 3 and 4 can have a thickness of 0.1 to 1.0 mm and are placed in large dimensions on the ceramic carrier 2 and connected to the ceramic carrier 2 by the DCB method. The large-area copper-ceramic substrate 1 is then cut into smaller units and processed further.

The copper layers 3 and 4 can furthermore have at least 99.95% Cu, preferably at least 99.99% Cu, at most 25 ppm Ag, at most 10 ppm, or preferably at most 5 ppm O.

In addition, the copper layers 3 and 4 can have a proportion of the elements Cd, Ce, Ge, V, Zn of, in each case, at most 0-1 ppm, and/or a proportion of the elements Bi, Se, Sn, Te of, in each case, at most 0-2 ppm, and/or a proportion of the elements Al, Sb, Ti, Zr of, in each case, at most 0-3 ppm, and/or a proportion of the elements As, Co, In, Mn, Pb, Si of, in each case, at most 0-5 ppm, and/or a proportion of the elements B, Be, Cr, Fe, Mn, Ni, P, S of, in each case, at most 0-10 ppm. The enumerated additional elements can be deliberately introduced into the microstructure by doping during the melting process immediately before casting, or they can already be present in the copper layers 3 and 4 during the production of the semi-finished copper products. In any case, the proportion of these elements, including additional impurities, should preferably be at most 50 ppm.

Furthermore, the copper layer according to a further preferred embodiment has a proportion of the elements Cd, Ce, Ge, V, Zn of at least 0.5 ppm and at most 5 ppm, a proportion of the elements Bi, Se, Sn, Te of at least 1.0 ppm and at most 8 ppm, a proportion of the elements Al, Sb, Ti, Zr of at least 1.0 ppm and at most 10 ppm, a proportion of the elements As, Co, In, Mn, Pb, Si of at least 1.0 ppm and at most 20 ppm, and a proportion of the elements B, Be, Cr, Fe, Mn, Ni, P, S of a total of at least 1.0 ppm and at most 50 ppm.

The quantitative proportions of the elements described are necessary in order to achieve the average grain size of the microstructure proposed according to the invention. The microstructure formation is caused in particular due to the grain refinement of the microstructure caused by the elements and to the reduction in secondary recrystallization in the microstructure during the bonding process. For example, the element As can change and in particular increase the recrystallization temperature, so that the microstructure no longer changes during the bonding process to such an extent that the average grain size is increased and thus moves outside the proposed range. Furthermore, the element Zr can be used to preserve the microstructure while maintaining the average grain size when exposed to temperature, since the Zr acts as an external seed.

1-17. (canceled)

18. A copper-ceramic substrate, comprising:
a ceramic carrier, and
a copper layer bonded to a surface of the ceramic carrier, wherein the copper layer has a free surface for forming a conductor structure and/or for securing bonding wires,
wherein the copper layer has a microstructure with an average grain size diameter of 200 to 500 μm.

19. The copper-ceramic substrate according to claim 18,
wherein the copper layer has an electrical conductivity of at least 50 MS/m.

20. The copper-ceramic substrate according to claim 18,
wherein the copper layer has a Vickers hardness of 40 to 100.

21. The copper-ceramic substrate according to claim 18,
wherein the copper layer has a proportion of at least 99.95% Cu.

22. The copper-ceramic substrate according to claim 21,
wherein the copper layer has a proportion of at most 25 ppm Ag.

23. The copper-ceramic substrate according to claim 21,
wherein the copper layer has a proportion of at most 10 ppm of O.

24. The copper-ceramic substrate according to claim 21,
wherein the copper layer has a proportion of the elements Cd, Ce, Ge, V, Zn of, in each case, at most 0-1 ppm.

25. The copper-ceramic substrate according to claim 21,
wherein the copper layer has a proportion of the elements Cd, Ce, Ge, V, Zn of a total of at least 0.5 ppm and at most 5 ppm.

26. The copper-ceramic substrate according to claim 21,
wherein the copper layer has a proportion of the elements Bi, Se, Sn, Te of, in each case, at most 0-2 ppm.

27. The copper-ceramic substrate according to claim 21,
wherein the copper layer has a proportion of the elements Bi, Se, Sn, Te of a total of at least 1.0 ppm and at most 8 ppm.

28. The copper-ceramic substrate according to claim 21,
wherein the copper layer has a proportion of the elements Al, Sb, Ti, Zr of, in each case, at most 0-3 ppm.

29. The copper-ceramic substrate according to claim 21,
wherein the copper layer has a proportion of the elements Al, Sb, Ti, Zr of a total of at least 1.0 ppm and at most 10 ppm.

30. The copper-ceramic substrate according to claim 21,
wherein the copper layer has a proportion of the elements As, Co, In, Mn, Pb, Si of, in each case, at most 0-5 ppm.

31. The copper-ceramic substrate according to claim 21,
wherein the copper layer has a proportion of the elements As, Co, In, Mn, Pb, Si of a total of at least 1.0 ppm and at most 20 ppm.

32. The copper-ceramic substrate according to claim 21,
wherein the copper layer has a proportion of the elements B, Be, Cr, Fe, Mn, Ni, P, S of, in each case, at most 0-10 ppm.

33. The copper-ceramic substrate according to claim 21,
wherein the copper layer has a proportion of the elements B, Be, Cr, Fe, Mn, Ni, P, S of a total of at least 1.0 ppm and at most of 50 ppm.

34. The copper-ceramic substrate according to claim 24,
wherein the copper layer has further impurities, of at most 50 ppm.
